(19) United States
(12) Patent Application Publication
(10) Pub. No.: US 2013/0223156 A1
(43) Pub. Date: Aug. 29, 2013

(54) NONVOLATILE MEMORY DEVICE AND MEMORY SYSTEM INCLUDING THE SAME

(71) Applicant: SAMSUNG ELECTRONICS CO., LTD., (US)

(72) Inventors: NamHee Lee, Seoul (KR); Kwangil Park, Yongin-si (KR); Il Han Park, Suwon-si (KR); Sunghwan Seo, Hwaseong-si (KR); Kihwan Choi, Seongnam-si (KR)

(73) Assignee: SAMSUNG ELECTRONICS CO., LTD., SUWON-SI (KR)

(21) Appl. No.: 13/721,892

(22) Filed: Dec. 20, 2012

(30) Foreign Application Priority Data
Feb. 29, 2012 (KR) 10-2012-0021058

(51) Int. Cl. G11C 16/34; G11C 16/10

(52) U.S. Cl. CPC G11C 16/3459; G11C 16/10
USPC 365/185.22; 365/185.27

(57) ABSTRACT

A program method is provided for a nonvolatile memory device, including a substrate and multiple memory cells formed in a pocket well in the substrate. The program method includes supplying a program voltage to a selected word line during a program execution period of a program loop, supplying a verification voltage to the selected word line during a verification period of the program loop, and supplying a negative voltage to the pocket well as a well bias voltage during the verification period.

### CROSS-REFERENCE TO RELATED APPLICATIONS

A claim for priority under 35 U.S.C §119 is made to Korean Patent Application No. 10-2012-0021058, filed Feb. 29, 2012, the entire contents of which are hereby incorporated by reference.

### BACKGROUND

The various embodiments described herein relate to a semiconductor memory device, and more particularly, to a nonvolatile memory device and a memory system including the same.

Semiconductor memories are usually considered to be among the most vital microelectronic components of digital logic system design, such as computers and microprocessor-based applications ranging from satellites to consumer electronics. Therefore, advances in fabrication of semiconductor memories, including process enhancements and technology developments through the scaling for higher densities and faster speeds, help establish performance standards for other digital logic families.

Generally, semiconductor memory devices may be characterized as volatile memory devices, such as random access memory (RAM), or non-volatile memory devices, such as read-only memory (ROM). In RAM, logic information may be stored by setting up the logic state of a bistable flip-flop, such as in a static random access memory (SRAM), or through charging a capacitor as in a dynamic random access memory (DRAM). In either case, the data are stored and can be read out as long as power is applied, but are lost when the power is turned off; hence, they are called volatile memories.

Non-volatile memories, such as mask read-only memory (MROM), programmable read-only memory (PROM), erasable programmable read-only memory (EPROM), and electrically erasable programmable read-only memory (EEPROM), are capable of storing the data, even with the power turned off. The non-volatile memory data storage mode may be permanent or reprogrammable, depending upon the fabrication technology used. Non-volatile memories are used for program and microcode storage in a wide variety of applications in computer, avionics, telecommunications, and consumer electronics industries. A combination of single-chip volatile as well as non-volatile memory storage modes is also available in devices such as non-volatile SRAM (nvSRAM) for use in systems that require fast, programmable non-volatile memory. In addition, many special memory architectures have evolved which contain some additional logic circuitry to optimize their performance for application-specific tasks.

In non-volatile memories, however, MROM, PROM, and EPROM are not free to be erased and written to by a system itself, so general users may not easily update stored contents. In contrast, EEPROM is capable of being electrically erased or written. Application of EEPROM is widened to auxiliary memories or to system programming where continuous updates are needed (e.g., flash EEPROM).

### SUMMARY

According to an illustrative embodiment of the inventive concept, a program method is provided for a nonvolatile memory device, including a substrate and multiple memory cells formed in a pocket well in the substrate. The program method includes supplying a program voltage to a selected word line during a program execution period of a program loop, supplying a verification voltage to the selected word line during a verification period of the program loop, and supplying a negative voltage to the pocket well as a well bias voltage during the verification period.

The program method may further include supplying a negative voltage or a ground voltage to the pocket well as the well bias voltage during the program execution period.

Supplying the verification voltage to the selected word line during the verification period may include stepwise increasing the verification voltage during the verification period. Supplying the negative voltage to the pocket well as the well bias voltage during the verification period may include stepwise decreasing or stepwise increasing the negative voltage, while stepwise increasing the verification voltage.

The stepwise increases in the verification voltage during the verification period may be divided into multiple groups, and the negative voltage applied as the well bias voltage during the verification period may vary based on the groups.

According to another illustrative embodiment of the inventive concept, a nonvolatile memory device includes a memory cell array, a voltage generator, and control logic. The memory cell array includes multiple memory cells formed in a well of a semiconductor substrate. The voltage generator is configured to generate word line voltages to be supplied to word lines connected to the memory cells in the memory cell array and a well bias voltage to be supplied to the well of the semiconductor substrate. The control logic is configured to control the voltage generator to supply a negative voltage to the well of the semiconductor substrate as the well bias voltage during at least one program loop of a program operation including multiple program loops.

Each of the program loops may include a program execution period and a verification period, the negative voltage being supplied to the well of the semiconductor substrate during the verification period of the at least one program loop.

The control logic may be further configured to control the voltage generator to supply zero volts to the well of the semiconductor substrate as the well bias voltage during the program execution period of the at least one program loop. The control logic may be further configured to control the voltage generator to constantly supply the negative voltage to the well of the semiconductor substrate during each program loop before a specific program loop, and to control the voltage generator to supply zero volts to the well of the semiconductor substrate during the program execution period and the negative voltage to the well of the semiconductor substrate during the verification period of the specific program loop and each program loop following the specific program loop, including the at least one program loop.

The control logic may be further configured to control the voltage generator to stepwise increase the verification voltage supplied to the selected word line during the verification period of the at least one program loop. The control logic may be further configured to control the voltage generator to stepwise increase or decrease the negative voltage supplied to the well of the semiconductor while stepwise increasing the verification voltage. The stepwise increases of the verification voltage during the verification period of the at least one program loop may be divided into groups, and the negative voltage supplied to the well of the semiconductor may stepwise increase or decrease on the basis of the groups.

The well of the semiconductor substrate may include a pocket p-well formed within an n-well of the semiconductor substrate. Also, the nonvolatile memory device may be a NAND flash memory device.

The nonvolatile memory device may further include a row decoder configured to select and drive rows of the memory cell array under control of the control logic, and a read/write circuit configured to operate as a read circuit during a read operation for reading data from the memory cell array under the control of the control logic, and to operate as a write circuit during a write operation for writing data in the memory cell array under control of the control logic.

According to another illustrative embodiment of the inventive concept, a memory system includes a nonvolatile memory device and a memory controller connected with the nonvolatile memory device through a channel. The memory controller is configured, in a standby mode, to provide the nonvolatile memory device with information indicating a data retention mode, the nonvolatile memory device being configured to respond to the information indicating the data retention mode by biasing a pocket well of a substrate, in which memory cells are formed, with a negative voltage.

The standby mode may indicate an operation state of the memory system in which no external and internal requests exist. The nonvolatile memory device and the memory controller may constitute a memory card or a solid state drive.

### BRIEF DESCRIPTION OF THE FIGURES

Illustrative, non-limiting embodiments will be more clearly understood from the following detailed description taken in conjunction with the accompanying drawings, wherein like reference numerals refer to like parts throughout the figures unless otherwise specified.

FIG. 1A is a block diagram schematically illustrating a nonvolatile memory device, according to an embodiment of the inventive concept.

FIG. 1B is a cross-sectional view taken along a dotted line I-I′ in FIG. 1A, according to an embodiment of the inventive concept.

FIG. 2 is a diagram illustrating threshold voltage distributions according to the number of bits stored in a memory cell.

FIG. 3 is a diagram illustrating a program method of a nonvolatile memory device, according to an embodiment of the inventive concept.

FIG. 4 is a diagram illustrating a program method of a nonvolatile memory device, according to another embodiment of the inventive concept.

FIG. 5 is a diagram illustrating a program method of a nonvolatile memory device, according to still another embodiment of the inventive concept.

FIGS. 6 to 9 are diagrams illustrating program methods of a nonvolatile memory device, according to other embodiments of the inventive concept.

FIG. 10 is a block diagram schematically illustrating a memory system, according to an embodiment of the inventive concept.

FIG. 11 is a block diagram schematically illustrating a memory controller in FIG. 10, according to an embodiment of the inventive concept.

FIG. 12 is a flowchart illustrating an operating method of a memory system, according to an embodiment of the inventive concept.

FIG. 13 is a block diagram schematically illustrating a computing system, according to an embodiment of the inventive concept.

FIG. 14 is a block diagram schematically illustrating a solid state drive, according to an embodiment of the inventive concept.

FIG. 15 is a block diagram schematically illustrating a storage using a solid state drive in FIG. 14, according to an embodiment of the inventive concept.

FIG. 16 is a block diagram schematically illustrating a storage server using a solid state drive in FIG. 14, according to an embodiment of the inventive concept.

FIG. 17 is a diagram schematically illustrating systems to which a data storage device according to embodiments of the inventive concept is applied.

FIG. 18 is a block diagram schematically illustrating a memory card, according to an embodiment of the inventive concept.

FIG. 19 is a block diagram schematically illustrating a digital still camera, according to an embodiment of the inventive concept.

FIG. 20 is a diagram schematically illustrating various systems to which a memory card in FIG. 18 is applied, according to embodiments of the inventive concept.

### DETAILED DESCRIPTION

Various embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. Also, in the drawings, the size and relative sizes of layers and regions may be exaggerated for clarity.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the present teachings.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or in other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

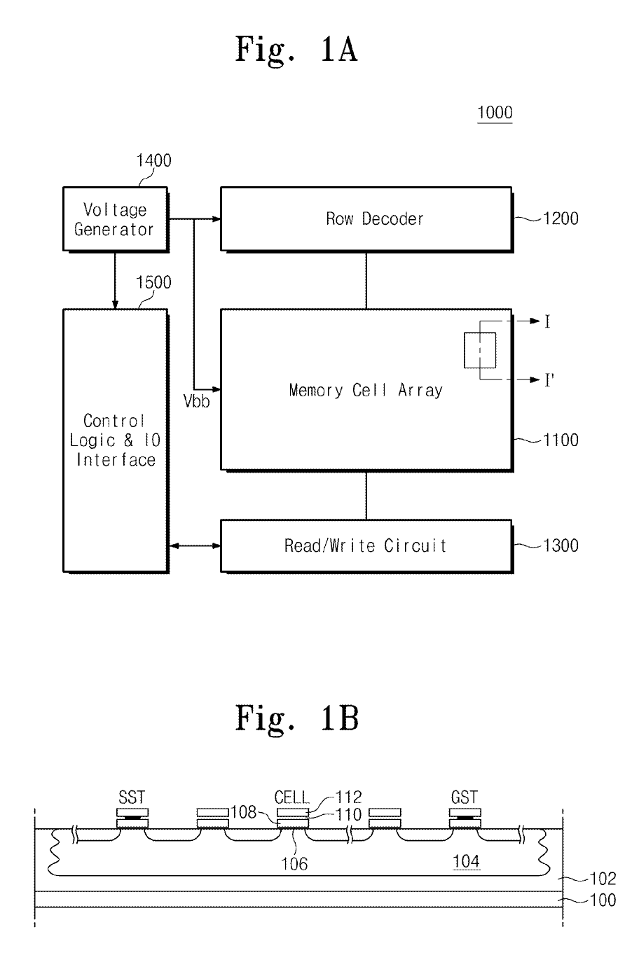

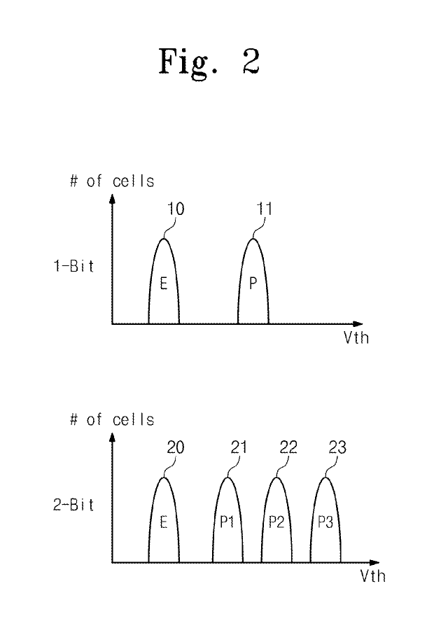

FIG. 1A is a block diagram schematically illustrating a nonvolatile memory device, according to an embodiment of the inventive concept.

Nonvolatile memory device 1000 may be a NAND flash memory device, for example. However, it is understood that the nonvolatile memory device 1000 is not limited to a NAND flash memory device. For example, embodiments of the inventive concept may include a NOR flash memory device, a resistive random access memory (RRAM) device, a phase-change memory (PRAM) device, a magnetroresistive random access memory (MRAM) device, a ferroelectric random access memory (FRAM) device, a spin transfer torque random access memory (STT-RAM), and the like. Further, the nonvolatile memory device 1000 may have a three-dimensional array structure, which may be referred to as a vertical NAND flash memory device. Embodiments of the inventive concept may be applied to a charge trap flash (CTF) memory device including a charge storage layer formed of an insulation film, as well as a flash memory device including a charge storage layer formed of a conductive floating gate.

Referring to FIG. 1A, the nonvolatile memory device 1000 includes a memory cell array 1100, a row decoder 1200, a read/write circuit 1300, a voltage generator 1400, and a control logic and input/output (I/O) interface block 1500 (or, control logic).

The memory cell array 1100 may include memory cells arranged in rows (lines) and columns (bit lines). The memory cells may form memory blocks, and the memory blocks may form one or more mats. The memory cells may be formed in a semiconductor substrate. For example, the memory cells may be formed in a pocket well (e.g., a pocket p-well) formed in the semiconductor substrate. However, embodiments of the inventive concept are not limited thereto. For example, the memory cells may be formed in semiconductor material layers electrically connected with a semiconductor substrate. The row decoder 1200 is controlled by the control logic and input/output interface block 1500, and performs selecting and driving on rows of the memory cell array 1100 (or, rows of memory blocks/mats in the memory cell array 1100).

The read/write circuit 1300 is controlled by the control logic and input/output interface block 1500, and may operate as a read circuit or a write circuit according to the mode of operation. For example, in a read operation, the read/write circuit 1300 operates as a read circuit which reads data from the memory cell array 1100 under the control of the control logic and input/output interface block 1500. In a write operation, the read/write circuit 1300 operates as a write circuit which writes data in the memory cell array 1100 under the control of the control logic and input/output interface block 1500.

The voltage generator 1400 is controlled by the control logic and input/output interface block 1500, and generates voltages for the nonvolatile memory device 1000. For example, the voltage generator 1400 may generate word lines voltages (e.g., a program voltage, a pass voltage, a verification voltage, a selection voltage, etc.) to be supplied to word lines of the memory cell array 1100 and a well bias voltage Vbb to be supplied to the semiconductor substrate (or, a p-well/pocket p-well) of the memory cell array 1100. The well bias voltage Vbb may be 0V or a negative voltage, for example, according to a mode of operation, as more fully described below.

The control logic and input/output interface block 1500 controls overall operation of the nonvolatile memory device 1000. The control logic and input/output interface block 1500 provides a data transfer channel between the nonvolatile memory device 1000 and an external device (e.g., a memory controller or a host). When a program operation is requested, the control logic and input/output interface block 1500 controls the voltage generator 1400 such that a negative voltage is applied to the substrate (or, a p-well/pocket p-well) where memory cells are formed. A period during which the substrate is biased with a negative voltage may be determined variously. For example, as discussed below, the period during which the substrate is biased with a negative voltage may include all program loops, only a verification period of each program loop, all program loops executed before a specific program loop and only a verification period of each program loop executed after the specific program loop, an erase verification period, or a period in which a read operation is performed. However, embodiments of the inventive concept are not limited thereto.

FIG. 1B is a cross-sectional view taken along a dotted line I-I′ in FIG. 1A, according to an embodiment of the inventive concept.

In particular, FIG. 1B illustrates a cross section on one of multiple strings in a NAND flash memory device as a nonvolatile memory device 1000. The remaining strings may be formed substantially the same as illustrated in FIG. 1B. The string includes a string selection transistor SST for selecting a string, a ground selection transistor GST for selecting a ground, and multiple memory cell transistors CELL connected between the string selection transistor SST and the ground selection transistor GST. Each memory cell transistor may include a tunnel oxide film 106, a floating gate 108, an interlayer insulation film 110, and a control gate 112. However, it is understood that the structure of the memory cell transistors is not limited thereto. The memory cell array 1100 may be formed in a pocket p-well 104, which is formed in an n-well 102 of semiconductor substrate 100. For example, in various embodiments, the pocket p-well 104 may be formed by high-energy ion injection in the n-well 102, and the n-well 102 may be a general diffusion well formed in the semiconductor substrate 100. The illustrative well structure depicted in FIG. 1B may be referred to as a triple well structure. Examples of triple well structures are disclosed in U.S. Patent App. Pub. No. 2009/0147583 to Kim (Jun. 11, 2009) and U.S. Pat. No. 7,936,002 to Kim et al. (May 3, 2011), which are hereby incorporated by reference.

FIG. 2 is a diagram illustrating threshold voltage distributions according to the number of bits stored in a memory cell.

The number of threshold voltage distributions may be determined according to the number of bits stored in a memory cell. For example, in the event that 1-bit data is stored in a memory cell, as illustrated in FIG. 2, two threshold voltage distributions 10 and 11 may be formed to correspond to an erase state E and a program state P, respectively. In the event that 2-bit data is stored in a memory cell, as illustrated in FIG. 2, four threshold voltage distributions 20, 21, 22, and 23 may be formed to correspond to an erase state E and three program states P1, P2, and P3, respectively.

A verification voltage may be applied to a word line to determine whether a program state is programmed to a target state. A memory cell having a threshold voltage lower than the verification voltage is determined to be an unprogrammed memory cell, while a memory cell having a threshold voltage equal to or higher than the verification voltage is determined to be a programmed memory cell. This determination may be based on the amount of current flowing through a memory cell. The amount of current flowing through a memory cell may change according to its threshold voltage. The amount of current flowing through a memory cell also may change due to various side effects resulting from scale-down of minimum feature size.

The current flowing through a memory cell may be referred to as cell current/drain current. One of the side effects may be a short channel effect. The short channel effect may lower the threshold voltage of a memory cell, which may increase the amount of cell/drain current flowing according to the same gate voltage. As the threshold voltage of a memory cell is lowered due to the short channel effect, a memory cell having a threshold voltage higher than the verification voltage may be determined to be an unprogrammed memory cell. Also, a memory cell having a threshold voltage lower than the verification voltage may experience more program loops. Thus, the threshold voltage distribution may be formed widely due to the short channel effect.

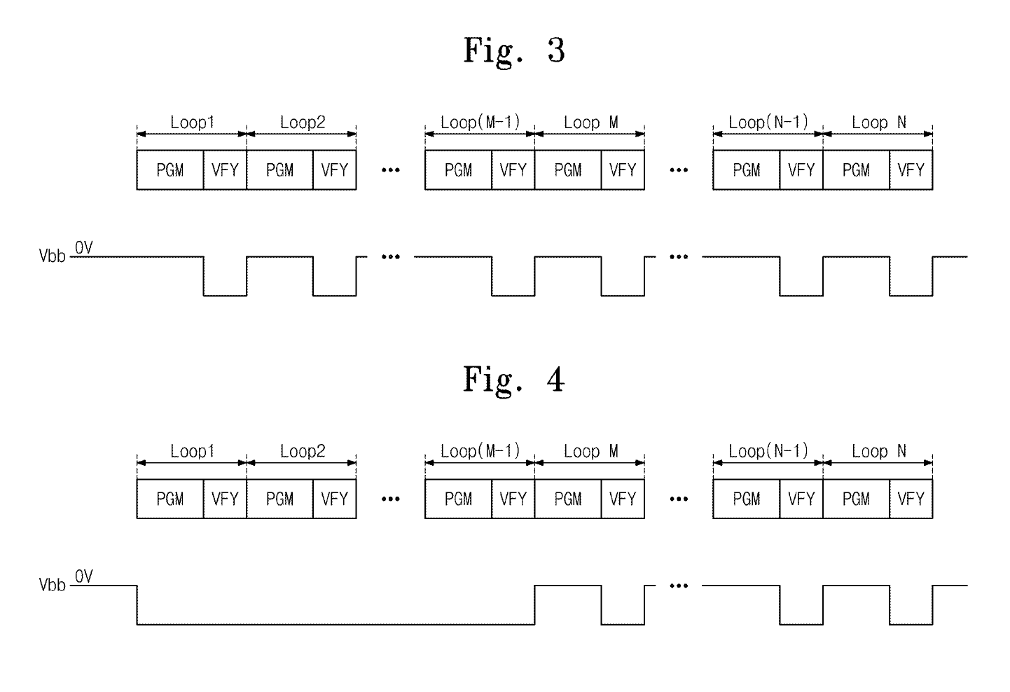

FIG. 3 is a diagram illustrating a program method of a nonvolatile memory device, according to an embodiment of the inventive concept.

A program operation of a nonvolatile memory device may be performed through program loops. Program loops are executed iteratively within the maximum program loop. Each program loop may include a program execution period and a verification period. During the program execution period, a selected word line is biased with a program voltage, generated by the voltage generator 1400, through the row decoder 1200 under the control of the control logic and input/output interface block 1500, and unselected word lines are biased with a pass voltage, generated by the voltage generator 1400, through the row selector 1200 under the control of the control logic and input/output interface block 1500. During the verification period, the selected word line is biased with a verification voltage, generated by the voltage generator 1400, through the row decoder 1200 under the control of the control logic and input/output interface block 1500, and the unselected word lines are biased with a pass voltage, generated by the voltage generator 1400, through the row decoder 1200 under the control of the control logic and input/output interface block 1500.

Examples of bias conditions of program execution and verification periods are disclosed in U.S. Pat. No. 7,940,567 to Moon et al. (May 10, 2011), which is hereby incorporated by reference.

As illustrated in FIG. 3, well bias voltage Vbb of 0V is applied to a substrate (e.g., semiconductor substrate 100) of the memory cell array 1100 during the program execution period of each program loop, while a negative voltage (lower than 0V) is applied as well bias voltage Vbb to the substrate of the memory cell array 1100 during the verification period of each program loop. As a negative voltage is applied to the substrate during the verification period, short channel effect is reduced. For example, the negative voltage may force a depletion layer formed at a junction of a memory cell to be reduced, thus reducing the short channel effect. Also, decrease in threshold voltage due to the short channel effect may be compensated by the negative voltage. In other words, variations in the threshold voltage may decrease using the same gate voltage (or, the same verification voltage). As variations in the threshold voltage decreases, the threshold voltage of a memory cell may be determined more exactly. Therefore, the threshold voltage distribution is improved by compensating for lowering of the threshold voltage due to the short channel effect using the negative voltage.

FIG. 4 is a diagram illustrating a program method of a nonvolatile memory device, according to another embodiment of the inventive concept.

In a program mode of operation, the control logic and input/output interface block 1500 determines when a current program loop reaches a specific program loop. When the current program loop has not reached the specific program loop, during program execution and verification periods of each program loop, the control logic and input/output interface block 1500 controls the voltage generator 1400 such that the substrate of the memory cell array 1100 is constantly biased with a negative voltage. That is, as illustrated in FIG. 4, before the current program loop has reached a specific program loop (e.g., Loop M), the substrate of the memory cell array 1100 is biased with a negative voltage during the program execution and verification periods of each program loop.

When it is determined that the current program loop reaches the specific program loop (e.g., Loop M), the substrate of the memory cell array 1100 is biased with a voltage of 0V during the program execution period of each program loop. That is, when the current program loop reaches a specific program loop (e.g., Loop M), the substrate of the memory cell array 1100 is biased with well bias voltage Vbb of 0V during the program execution period of each program loop, while the substrate of the memory cell array 1100 is biased with a negative voltage during the verification period of each program loop.

A decrease in threshold voltage due to the short channel effect may be compensated by the negative voltage. As variations in the threshold voltage decreases, the threshold voltage of a memory cell may be determined more exactly. Therefore, the threshold voltage distribution is improved by compensating for lowering of the threshold voltage due to the short channel effect using the negative voltage.

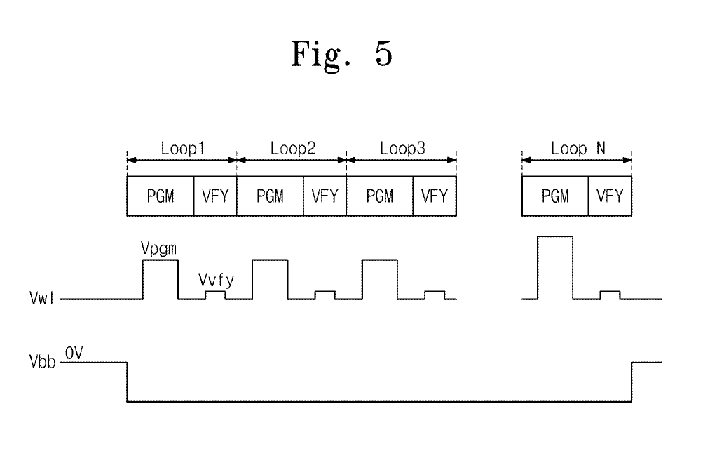

FIG. 5 is a diagram illustrating a program method of a nonvolatile memory device, according to still another embodiment of the inventive concept.

As illustrated in FIG. 5, in all program loops, a negative voltage is constantly applied to the substrate of the memory cell array 1100 as the well bias voltage Vbb. Since the negative voltage is constantly applied to the substrate of the memory cell array 1100 as the well bias voltage Vbb in all program loops, a decrease in threshold voltage due to the short channel effect may be compensated for by the negative voltage. As variation in the threshold voltage decreases, the threshold voltage of a memory cell may be determined more exactly. Thus, the threshold voltage distribution may improve by compensating for lowering of the threshold voltage due to the short channel effect using the negative voltage.

A program voltage (Vpgm) is applied to a selected word line as word line voltage (Vwl) selected in a program execution period. Also, one or more verification voltages (Vvfy) are applied to a selected word line as the word line voltage selected in a verification period, according to the number of data bits stored in a memory cell. For example, if 1-bit data is stored in a memory cell, one verification voltage is applied to the selected word line in a verification period. If N-bit data is stored in a memory cell, (2^{N}−1) verification voltages are applied to the selected word line in a verification period. For example, when 2-bit data is stored in a memory cell, three verification voltages are applied to the selected word line in the verification period. Upon variation of verification voltages, a negative well bias voltage Vbb may be kept or varied, as more fully described below.

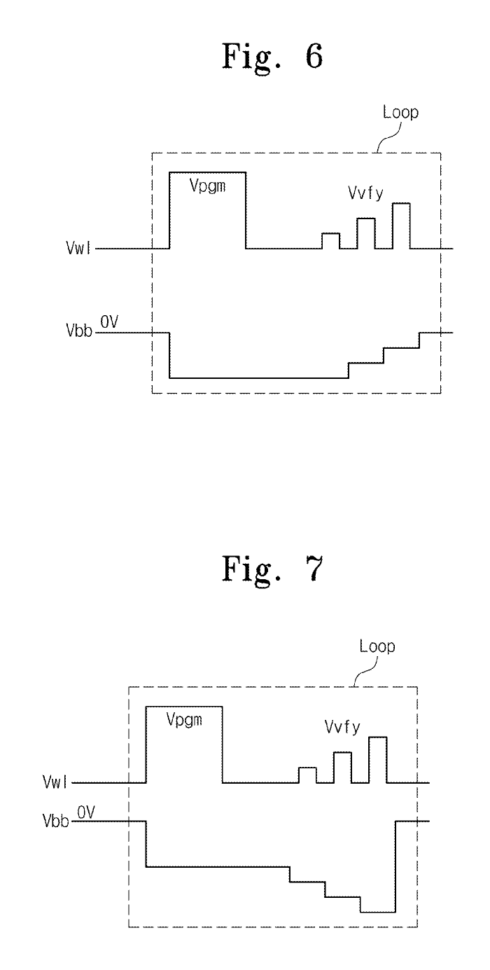

FIGS. 6 to 9 are diagrams illustrating program methods of a nonvolatile memory device, according to other embodiments of the inventive concept. For ease of illustration, one program loop is illustrated in FIGS. 6 to 9. However, it is understood that the program methods described in FIGS. 3 to 5 may be applied to the program methods described in FIGS. 6 to 9.

FIGS. 6 and 7 are directed to embodiments in which a negative voltage is applied to the memory cell array 1100 as well bias voltage Vbb during program execution and verification periods, and the verification voltage stepwise increases during the verification period. Referring to FIG. 6, as the verification voltage applied to a selected word line in the verification period stepwise increases, the negative voltage applied to the memory cell array 1100 as the well bias voltage Vbb stepwise increases. In comparison, as illustrated in FIG. 7, as the verification voltage applied to a selected word line in the verification period stepwise increases, the negative voltage applied to the memory cell array 1100 as the well bias voltage Vbb stepwise decreases.

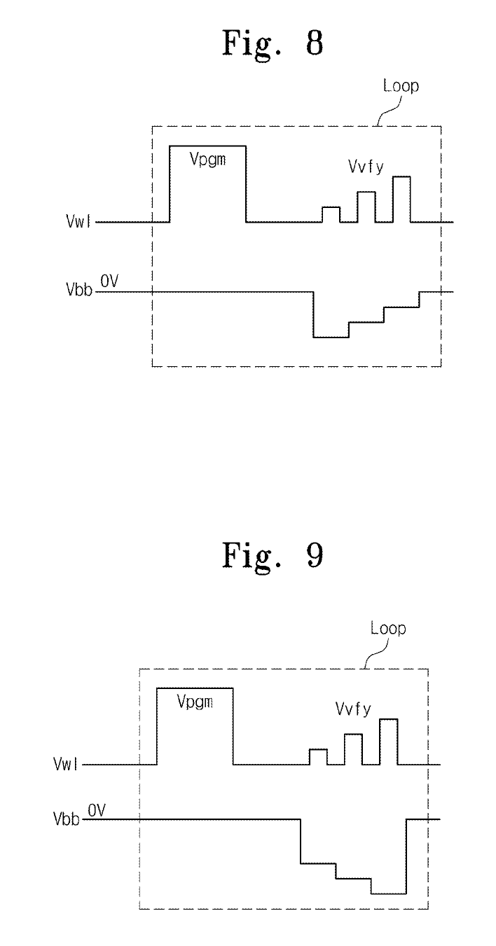

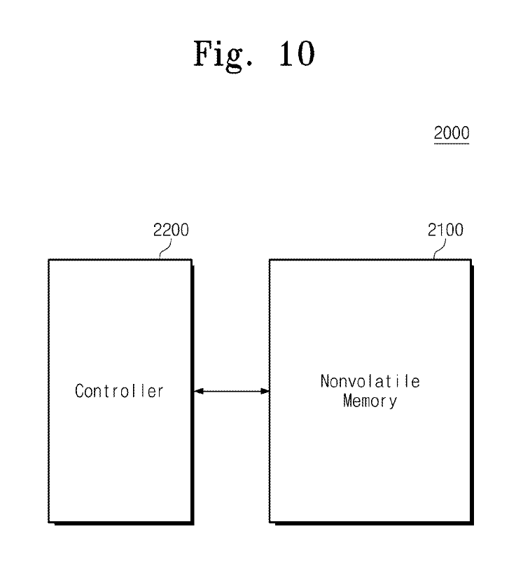

FIGS. 8 and 9 are directed to embodiments in which a well bias voltage Vbb of 0V is applied to the memory cell array 1100 during a program execution period, a negative voltage is applied to the memory cell array 1100 as the well bias voltage Vbb during a verification period, and a verification voltage stepwise increases during the verification period. Referring to FIG. 8, when the verification voltage applied to a selected word line in the verification period stepwise increases, the negative voltage applied to the memory cell array 1100 as the well bias voltage Vbb also stepwise increases. In comparison, as illustrated in FIG. 9, when the verification voltage applied to a selected word line in the verification period stepwise increases, the negative voltage applied to the memory cell array 1100 as the well bias voltage Vbb stepwise decreases.

In the embodiments depicted in FIGS. 6 to 9, it is assumed for convenience of explanation that 2-bit data is stored in a memory cell, and thus three verification voltages are applied (e.g., in verification voltage steps), as discussed above. The number of verification voltage steps may increase when three or more data bits are stored in a memory cell. In this case, the verification voltage steps may be divided into multiple groups, and the negative voltage steps applied as the well bias voltage Vbb during the verification period may vary on the basis of the groups. A negative voltage varied on the basis of the groups may comply with one of manners described above with reference to FIGS. 6 to 9.

In illustrative embodiments, an operation of biasing a bulk with a negative voltage may be selectively performed on the basis of a program-erase cycle.

FIG. 10 is a block diagram schematically illustrating a memory system, according to an embodiment of the inventive concept.

Referring to FIG. 10, a memory system 2000 according to an embodiment of the inventive concept includes a nonvolatile memory device 2100 and a memory controller 2200. The nonvolatile memory device 2100 may be configured substantially the same as the embodiment illustrated in FIG. 1A, and thus the description will not be repeated. The memory controller 2200 may be configured to control the nonvolatile memory device 2100 according to a request (e.g., a write request, a read request, etc.) of an external device (e.g., host). The memory controller 2200 may be configured to control the nonvolatile memory device 2100 according to an internal request (e.g., an operation associated with sudden power-off, background operations such as merge, garbage collection, etc.) without an external request. The nonvolatile memory device 2100 operates in response to the control of the memory controller 2200, and may be used as a type of storage medium which stores data information. The storage medium may be formed of one or more memory chips. The nonvolatile memory device 2100 may communicate with the memory controller 2200 via one or more channels. The nonvolatile memory device 2100 may include a NAND flash memory device, for example.

The memory controller 2200 according to an embodiment of the inventive concept may determine whether the memory system 2000 is in a standby mode. The standby mode may indicate an operating state of the memory system 2000 where no internal and external requests exist. When the memory system 2000 is determined to be in the standby mode, the memory controller 2200 controls the nonvolatile memory device 2100 to operate in a data retention mode. The data retention mode may be initiated in various manners, without departing from the scope of the present teachings. For example, a command indicating the data retention mode may be used, although the inventive concept is not limited thereto. When the nonvolatile memory device 2100 enters the data retention mode, the control logic and input/output interface block 1500 may control voltage generator 1400 such that a substrate of the memory cell array 1100 is biased with a negative voltage.

An electric field may be formed between a gate (or, charge storing layer) of a programmed memory cell and a substrate, with no voltage applied to a word line. Charges of the gate (or, charge storing layer) of the programmed memory cell may leak by the electric field, which may cause the threshold voltage distribution to shift toward a lower voltage. According to various embodiments, as the substrate of the memory cell array 1100 is biased with a negative voltage in the standby mode, the electric field formed between the gate (or, charge storing layer) of the programmed memory cell and the substrate is reduced. Therefore, the leakage of charges of the gate (or, charge storing layer) through the electric field is suppressed or prevented.

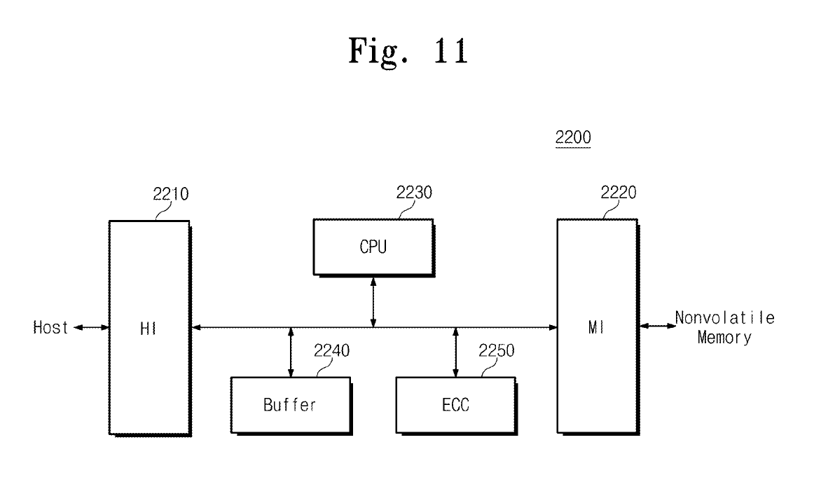

FIG. 11 is a block diagram schematically illustrating a memory controller as shown in FIG. 10, according to an embodiment of the inventive concept. Referring to FIG. 11, the memory controller 2200 includes a host interface 2210 as a first interface, a memory interface 2220 as a second interface, a central processing unit (CPU) 2230, a buffer memory 2240, and an error detecting and correcting (ECC) circuit 2250.

The host interface 2210 is configured to interface with an external device (for example, a host), and the memory interface 2220 is configured to interface with the nonvolatile memory device 2100 illustrated in FIG. 10. The CPU 2230 is configured to control overall operation of the memory controller 2200, and may operate firmware, such as Flash Translation Layer (FTL), for example. The CPU 2230 is configured to determine when the memory system 2000 is in standby mode. When the memory system 2000 is determined to be in the standby mode, the CPU 2230 controls the nonvolatile memory device 2100 through the memory interface 2220 to operate in the data retention mode. The buffer memory 2240 temporarily stores data transferred from an external device via the host interface 2210 or data transferred from the nonvolatile memory device 2100 via the memory interface 2220. The ECC circuit 2250 is configured to encode data to be stored in the nonvolatile memory device 2100 and to decode data read out from the nonvolatile memory device 2100.

Although not illustrated in figures, the memory controller 2200 may further include a randomizer/de-randomizer configured to randomize data to be stored in the nonvolatile memory device 2100 and to de-randomize data read from the nonvolatile memory device 2100. An example of the randomizer/de-randomizer is disclosed in U.S. Patent App. Pub. No. 2010/0088574 to Kim et al. (Apr. 8, 2010), which is hereby incorporated by reference.

In illustrative embodiments, the host interface 2210 may include one of computer bus standards, storage bus standards, and iFCPPeripheral bus standards, or a combination of two or more standards. The computer bus standards may include S-100 bus, Mbus, Smbus, Q-Bus, ISA, Zorro II, Zorro III, CAMAC, FASTBUS, LPC, EISA, VME, VXI, NuBus, TURBOchannel, MCA, Sbus, VLB, PCI, PXI, HP GSC bus, CoreConnect, InfiniBand, UPA, PCI-X, AGP, PCIe, Intel QuickPath Interconnect, Hyper Transport, and the like. The storage bus standards may include ST-506, ESDI, SMD, Parallel ATA, DMA, SSA, HIPPI, USB MSC, FireWire(1394), Serial ATA, eSATA, SCSI, Parallel SCSI, Serial Attached SCSI, Fibre Channel, iSCSI, SAS, RapidIO, FCIP, etc. The iFCPPeripheral bus standards may include Apple Desktop Bus, HIL, MIDI, Multibus, RS-232, DMX512-A, EIA/RS-422, IEEE-1284, UNI/O, 1-Wire, I2C, SPI, EIA/RS-485, USB, Camera Link, External PCIe, Light Peak, Multidrop Bus, and the like.

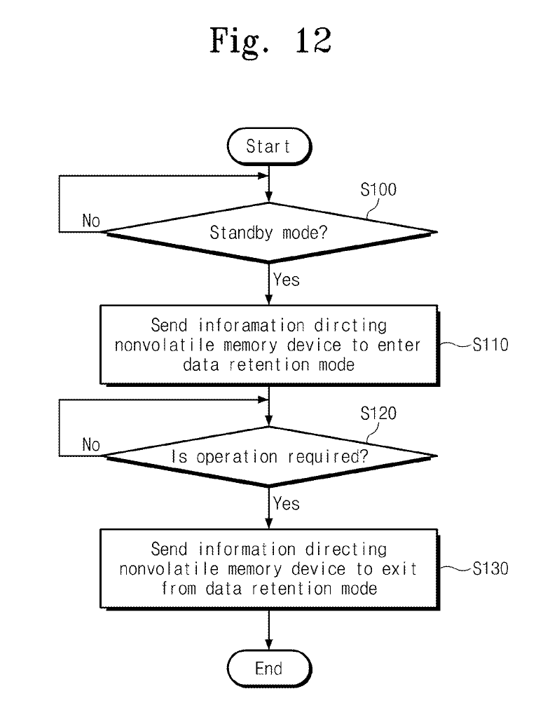

FIG. 12 is a flowchart illustrating an operating method of a memory system, according to an embodiment of the inventive concept.

Referring to FIG. 12, memory controller 2200 determines whether the operating state of memory system 2000 is in a standby mode in operation S100. When it is determined that the memory system 2000 is not in the standby mode, the method returns to operation S100. Alternatively, when it is determined that the memory system 200 is not in the standby mode, the method may proceed to a routine (not shown) for executing another operation. When it is determined that the memory system 2000 is in the standby mode, the method proceeds to operation S110.

In operation S110, the memory controller 2200 sends information (e.g., a command) directing the nonvolatile memory device 2100 to enter a data retention mode. In response, the control logic and input/output interface block 1500 of the nonvolatile memory device 2100 controls the voltage generator 1400 such that a negative voltage is applied as a well bias voltage Vbb to the memory cell array 1100. Since the substrate of the memory cell array 1100 is biased with the negative voltage in the standby mode, an electric field between a gate (or, a charge storing layer) of a programmed memory cell and the substrate is reduced. Therefore, the leakage of charges of the gate (or, charge storing layer) by the electric field is suppressed or prevented.

In operation S120, the memory controller 2200 determines whether an external request or an internal request is generated requiring an operation. When no operation is required, the method proceeds to operation S120. When an operation is required, the method proceeds to operation S130, in which the memory controller 2200 provides the nonvolatile memory device 2100 with information (e.g., a command) directing it to exit from the data retention mode. In response to the information directing the nonvolatile memory device 2100 to exit from the data retention mode, the control logic and input/output interface block 1500 of the nonvolatile memory device 2100 controls the voltage generator 1400 such that a well bias voltage Vbb of 0V is applied to the memory cell array 1100. Afterwards, the method may be ended.

For ease of description, the operating method of the memory system 2000 described above assumes that operations S100 to S130 occur sequentially. However, it is understood that the inventive concept is not limited thereto. For example, the operations S100 and S110 may constitute one routine, and the operations S120 and S130 may constitute another routine. Alternatively, the operations S100 and S110 may constitute a routine, and the operations S120 and S130 may be skipped. In the latter case, the nonvolatile memory device 2100 may exit from the data retention mode in response to one of the remaining commands, other than the command directing the nonvolatile memory device 2100 to enter to the data retention mode.

Although not shown, operations of determining a standby mode, entering a data retention mode, and exiting from the data retention mode can be automatically executed by the nonvolatile memory device 2100 without intervention of the memory controller 2200, or through partial intervention of the memory controller 2200.

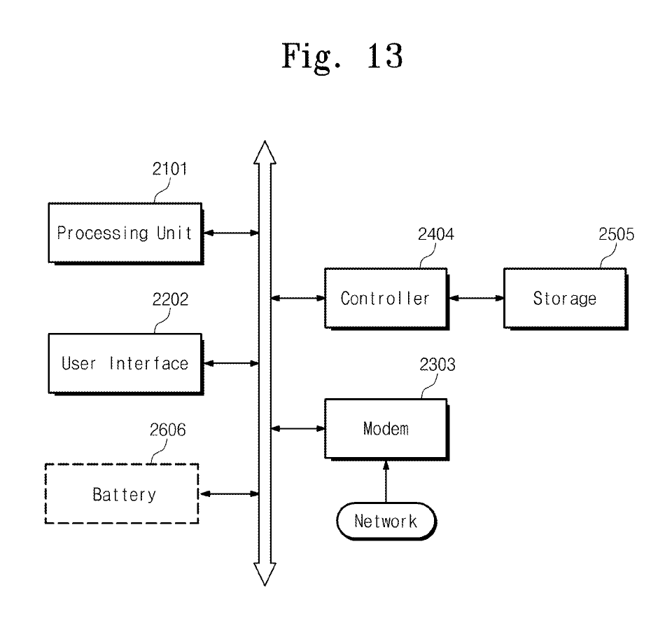

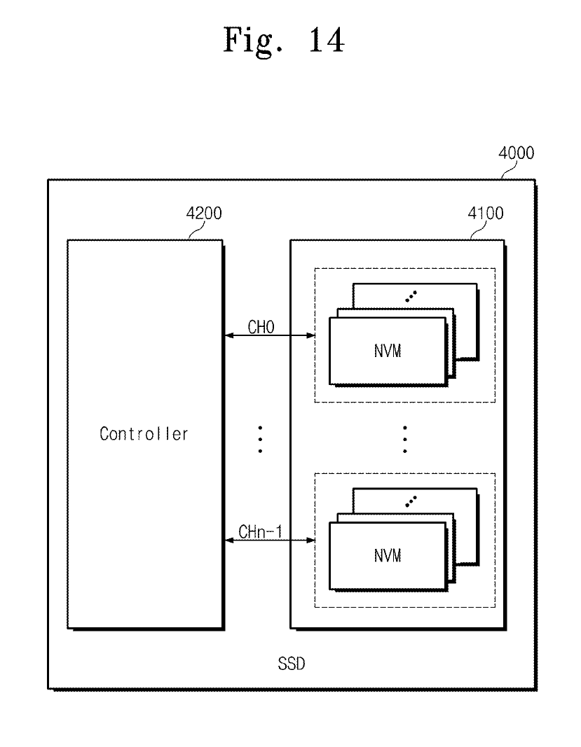

FIG. 13 is a block diagram schematically illustrating a computing system, according to an embodiment of the inventive concept.

Referring to FIG. 13, the computing system includes a processing unit 2101, a user interface 2202, a modem 2303 such as a baseband chipset, a memory controller 2404, and a nonvolatile memory device 2505 as a storage medium. The nonvolatile memory device 2505 may be configured substantially the same as illustrated in FIG. 1A, for example. That is, when a program operation is requested, the nonvolatile memory device 2505 is configured such that a negative voltage may be applied to a substrate (or, a p-well/pocket p-well) in which memory cells are formed. The memory controller 2404 may be configured substantially the same as illustrated in FIG. 10, for example. That is, the memory controller 2404 determines whether an operating state is in a standby mode. When the operating state is determined to be in the standby mode, the memory controller 2404 controls the nonvolatile memory device 2505 to operate in a data retention mode. N-bit data (N being 1 or more integer) processed/to be processed by the processing unit 2101 may be stored in the nonvolatile memory device 2505 through the memory controller 2404. In the event that the computing system is a mobile device, a battery 2606 is further included in the computing system to supply an operating voltage thereto. Although not illustrated in FIG. 10, the computing system may further include an application chipset, a camera image processor (CIS), a mobile DRAM, and the like.

FIG. 14 is a block diagram schematically illustrating a solid state drive, according to an embodiment of the inventive concept.

Referring to FIG. 14, a solid state drive (SSD) 4000 includes storage medium 4100 and a controller 4200. The storage medium 4100 is connected with the controller 4200 via multiple channels CHO to CHn−1, each of which is commonly connected with multiple nonvolatile memories NVM. Each nonvolatile memory NVM may be configured substantially the same as illustrated in FIG. 1A, for example. That is, when a program operation is requested, each nonvolatile memory NVM is configured such that a negative voltage may be applied to a substrate (or, a p-well/pocket p-well) in which memory cells are formed. The memory controller 4200 may be configured substantially the same as illustrated in FIG. 10, for example. That is, the memory controller 4200 may determine whether an operating state is in a standby mode. When the operating state is determined to be in the standby mode, the memory controller 4200 may control each nonvolatile memory NVM to operate in a data retention mode.

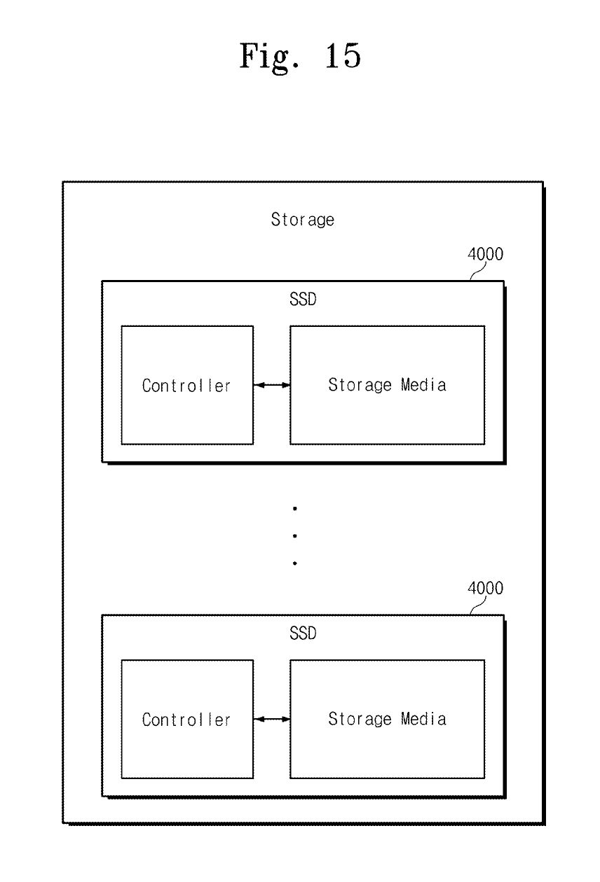

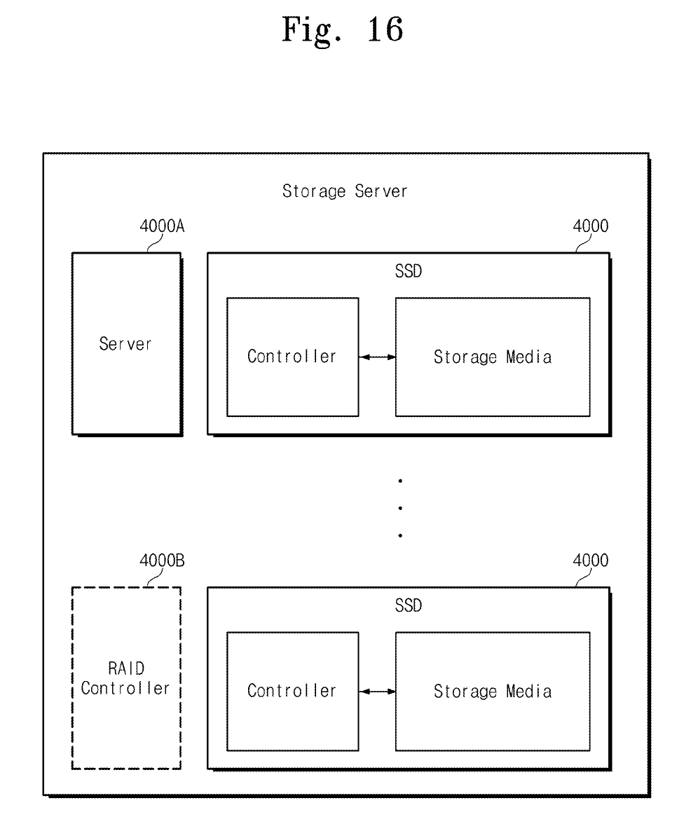

FIG. 15 is a block diagram schematically illustrating a storage using the solid state drive depicted in FIG. 14, and FIG. 16 is a block diagram schematically illustrating a storage server using the solid state drive in FIG. 14, according to embodiments of the inventive concept.

The SSD 4000 according to an embodiment may be used for storage. In particular, referring to FIG. 15, storage is formed by multiple SSDs 4000, each of which may be configured as described above with reference to FIG. 14. Also, the SSD 4000 according to an embodiment may be used to configure a storage sever. In particular, referring to FIG. 16, a storage server includes multiple solid state drives 4000, each of which may be configured the same as described above with reference to FIG. 14, and a server 4000A. Further, it is understood that a known RAID controller 4000B may be provided in the storage server, as well.

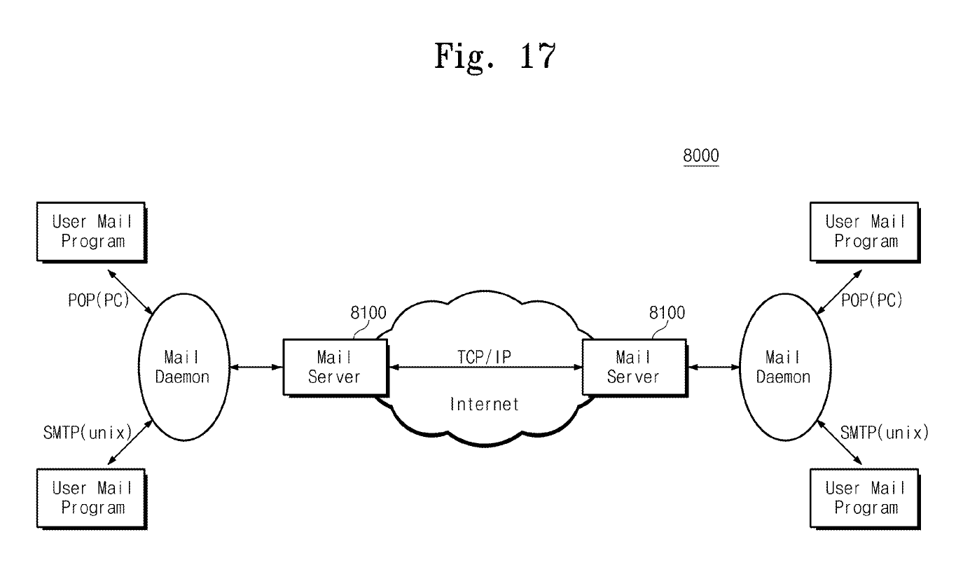

FIG. 17 is a diagram schematically illustrating systems to which a data storage device, according to embodiments of the inventive concept, is applied.

Referring to FIG. 17, a solid state drive including a data storage device according to an embodiment of the inventive concept may be applied to mail servers 8100 in system 8000. In the depicted configuration, the mail servers 8100 are connected across a packet-switching network, such as the Internet, e.g., using transmission control protocol/Internet protocol (TCP/IP). The mail servers 8100 may interface with User Mail Programs via corresponding Mail Daemons in a known manner.

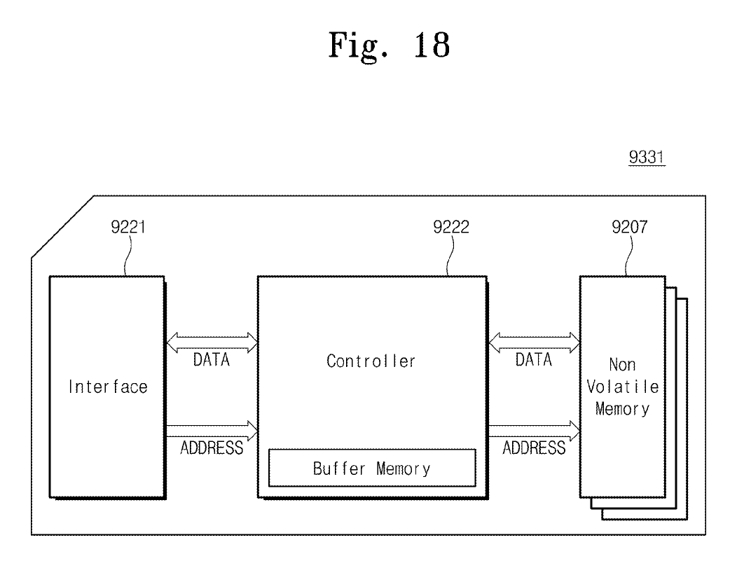

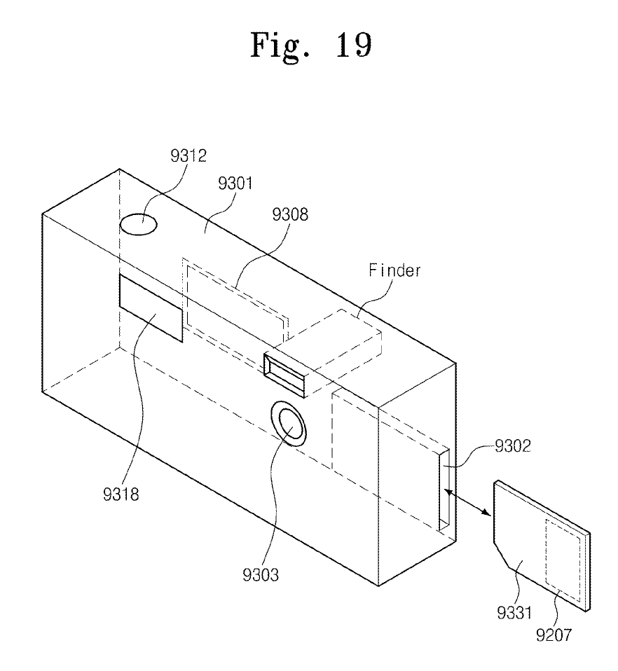

FIG. 18 is a block diagram schematically illustrating a memory card, according to an embodiment of the inventive concept. The memory card may be, for example, an MMC card, an SD card, a multiuse card, a micro-SD card, a memory stick, a compact SD card, an ID card, a PCMCIA card, an SSD card, a chip-card, a smartcard, an USB card, or the like.

Referring to FIG. 18, memory card 9331 includes an interface circuit 9221 for interfacing with an external device, a controller 9222 (including a buffer memory) for controlling operations of the memory card 9331, and at least one nonvolatile memory 9207. The controller 9222 may be a processor configured to control write and read operations of the nonvolatile memory device 9207. The controller 9222 is coupled with the nonvolatile memory device 9207 and the interface circuit 9221 via a data bus and an address bus. The nonvolatile memory device 9207 may be configured substantially the same as illustrated in FIG. 1A, for example. That is, when a program operation is requested, the nonvolatile memory device 9207 is configured such that a negative voltage is applied to a substrate (or, a p-well/pocket p-well) in which memory cells are formed. The controller 9222 may be configured substantially the same as illustrated in FIG. 10, for example. That is, the controller 9222 may determine whether an operating state is in a standby mode. When the operating state is determined to be in the standby mode, the controller 9222 controls the nonvolatile memory device 9207 to operate in a data retention mode.

FIG. 19 is a block diagram schematically illustrating a digital still camera, according to an embodiment of the inventive concept.

Referring to FIG. 19, a digital still camera includes a body 9301, a slot 9302, a lens 9303, a display circuit 9308, a shutter button 9312, and a strobe 9318. The memory card 9331, including the nonvolatile memory device 9207, is insertable in the slot 9302. The nonvolatile memory device 9207 may be configured substantially the same as illustrated in FIG. 1A, for example, as discussed above. That is, when a program operation is requested, the nonvolatile memory device 9207 is configured such that a negative voltage may be applied to a substrate (or, a p-well/pocket p-well) in which memory cells are formed. The memory card 9331 may further include the controller 9222 (not shown in FIG. 19), which may be configured substantially the same as illustrated in FIG. 10, for example. That is, the controller may determine whether an operating state is in a standby mode. When the operating state is determined to be in the standby mode, the controller controls the nonvolatile memory device 9331 to operate in a data retention mode.

If the memory card 9331 is a contact type, an electric circuit on a circuit board may electrically connect with the memory card 9331 (via the interface 9221) when the memory card 9331 is inserted in the slot 9302. In the event that the memory card 9331 is a non-contact type, an electric circuit on a circuit board may communicate with the memory card 9331 (via the interface 9221) using radio-frequency signals, for example.

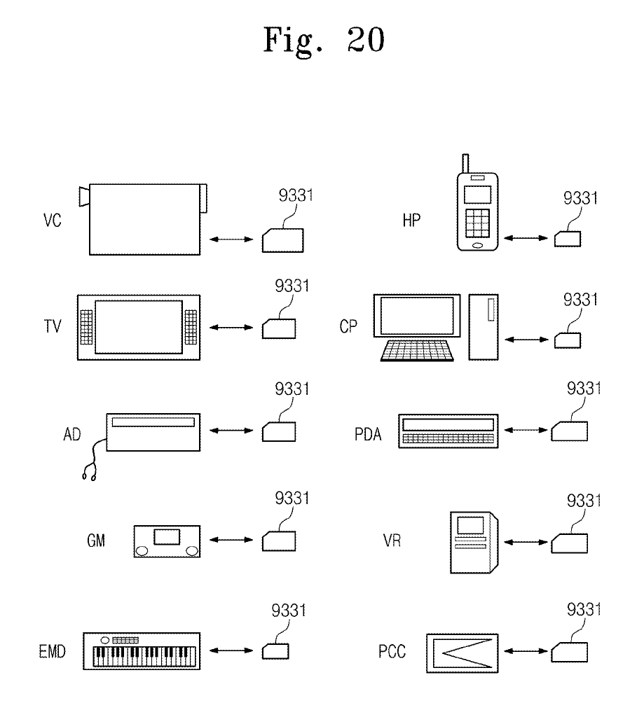

FIG. 20 is a diagram schematically illustrating various systems to which a memory card in FIG. 18 is applied, according to embodiments of the inventive concept.

Referring to FIG. 20, the memory card 9331 may be applied to a video camera VC, a television TV, an audio device AD, a game machine GM, an electronic music device EMD, a cellular phone HP, a computer CP, a Personal Digital Assistant (PDA), a voice recorder VR, and a PC card PCC. Of course, the memory card 9331 may be used with various other electronic devices without departing from the scope of the present teachings.

In an illustrative embodiment, memory cells may be formed of a variable resistance memory cell. Examples of a variable resistance memory cell and a memory device including the same are disclosed in U.S. Pat. No. 7,529,124 to Cho et al. (May 5, 2009), which is hereby incorporated by reference.

In other embodiments, memory cells may be formed of one of various cell structures having a charge storage layer. Cell structures having a charge storage layer include a charge trap flash structure using a charge trap layer, a stack flash structure in which arrays are stacked in multiple layers, a source-drain free flash structure, a pin-type flash structure, and the like. In still other example embodiments, a memory device has a charge trap flash structure as a charge storage layer, examples of which are disclosed in U.S. Pat. No. 6,858,906 to Lee et al. (Feb. 22, 2005) and U.S. Patent App. Pub. Nos. 2004/0169238 to Lee et al. (Sep. 2, 2004) and 2006/0180851 to Lee et al. (Aug. 17, 2006), which are hereby incorporated by reference. An example of a source-drain free flash structure is disclosed in KR Patent No. 673020, which is hereby incorporated by reference.

A non-volatile memory device and/or a memory controller according to embodiments of the inventive concept may be packed using various types of packages. For example, the non-volatile memory device or the memory controller may be packed using packages such as PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A program method of a nonvolatile memory device comprising a substrate and a plurality of memory cells formed in a pocket well in the substrate, the program method comprising:
supplying a program voltage to a selected word line during a program execution period of a program loop;
supplying a verification voltage to the selected word line during a verification period of the program loop; and
supplying a negative voltage to the pocket well as a well bias voltage during the verification period.

2. The program method of claim 1, further comprising:
supplying a negative voltage or a ground voltage to the pocket well as the well bias voltage during the program execution period.

3. The program method of claim 2, wherein supplying the verification voltage to the selected word line during the verification period comprises stepwise increasing the verification voltage during the verification period.

4. The program method of claim 3, wherein supplying the negative voltage to the pocket well as the well bias voltage during the verification period comprises stepwise decreasing the negative voltage, while stepwise increasing the verification voltage.

5. The program method of claim 3, wherein supplying the negative voltage to the pocket well as the well bias voltage during the verification period comprises stepwise increasing the negative voltage, while stepwise increasing the verification voltage.

6. The program method of claim 3, wherein the stepwise increases in the verification voltage during the verification period are divided into a plurality of groups, and the negative voltage applied as the well bias voltage during the verification period varies based on the plurality of groups.

7. A nonvolatile memory device comprising:
a memory cell array comprising a plurality of memory cells formed in a well of a semiconductor substrate;
a voltage generator configured to generate word line voltages to be supplied to word lines connected to the plurality of memory cells in the memory cell array and a well bias voltage to be supplied to the well of the semiconductor substrate; and
a control logic configured to control the voltage generator to supply a negative voltage to the well of the semiconductor substrate as the well bias voltage during at least one program loop of a program operation comprising a plurality of program loops.

8. The nonvolatile memory device of claim 7, wherein each of the plurality of program loops comprises a program execution period and a verification period and the negative voltage is supplied to the well of the semiconductor substrate during the verification period of the at least one program loop.

9. The nonvolatile memory device of claim 8, wherein the control logic is further configured to control the voltage generator to supply zero volts to the well of the semiconductor substrate as the well bias voltage during the program execution period of the at least one program loop.

10. The nonvolatile memory device of claim 8, wherein the control logic is further configured to control the voltage generator to constantly supply the negative voltage to the well of the semiconductor substrate during each program loop before a specific program loop, and
wherein the control logic is further configured to control the voltage generator to supply zero volts to the well of the semiconductor substrate during the program execution period and the negative voltage to the well of the semiconductor substrate during the verification period of the specific program loop and each program loop following the specific program loop, including the at least one program loop.

11. The nonvolatile memory device of claim 8, wherein the control logic is further configured to control the voltage generator to stepwise increase the verification voltage supplied to the selected word line during the verification period of the at least one program loop.

12. The nonvolatile memory device of claim 11, wherein the control logic is further configured to control the voltage generator to stepwise increase the negative voltage supplied to the well of the semiconductor while stepwise increasing the verification voltage.

13. The nonvolatile memory device of claim 11, wherein the control logic is further configured to control the voltage generator to stepwise decrease the negative voltage supplied to the well of the semiconductor while stepwise increasing the verification voltage.

14. The nonvolatile memory device of claim 11, wherein the stepwise increases of the verification voltage during the verification period of the at least one program loop are divided into a plurality of groups, and the negative voltage supplied to the well of the semiconductor stepwise increases or decreases on the basis of the plurality of groups.

15. The nonvolatile memory device of claim 7, wherein the well of the semiconductor substrate comprises a pocket p-well formed within an n-well of the semiconductor substrate.

16. The nonvolatile memory device of claim 7, further comprising:
a row decoder configured to select and drive rows of the memory cell array under control of the control logic; and
a read/write circuit configured to operate as a read circuit during a read operation for reading data from the memory cell array under the control of the control logic, and to operate as a write circuit during a write operation for writing data in the memory cell array under control of the control logic.

17. The nonvolatile memory device of claim 7, wherein the nonvolatile memory device is a NAND flash memory device.

18. A memory system comprising:
a nonvolatile memory device; and
a memory controller connected with the nonvolatile memory device through a channel, wherein the memory controller is configured, in a standby mode, to provide the nonvolatile memory device with information indicating a data retention mode, the nonvolatile memory device being configured to respond to the information indicating the data retention mode by biasing a pocket well of a substrate, in which memory cells are formed, with a negative voltage.

19. The memory system of claim 18, wherein the standby mode indicates an operation state of the memory system in which no external and internal requests exist.

20. The memory system of claim 18, wherein the nonvolatile memory device and the memory controller constitute a memory card or a solid state drive.
